(19) United States
(12) Patent Application Publication
(10) Pub. No.: US 2024/0222558 A1
(43) Pub. Date: Jul. 4, 2024

(54) LIGHT EMITTING DIODE, MANUFACTURING METHOD AND LIGHT EMITTING DEVICE

(71) Applicant: Hubei Sanan Optoelectronics Co., Ltd., Hubei (CN)

(72) Inventors: Biao WEI, Hubei (CN); Xuyang LIU, Hubei (CN)

(73) Assignee: Hubei Sanan Optoelectronics Co., Ltd., Hubei (CN)

(21) Appl. No.: 18/536,249

(22) Filed: Dec. 12, 2023

(30) Foreign Application Priority Data
Dec. 28, 2022 (CN) 202211696015.7

(51) Int. Cl. H01L 33/38; H01L 33/00; H01L 33/14

(52) U.S. Cl. CPC H01L 33/38; H01L 33/0095; H01L 33/145

(57) ABSTRACT

A light emitting diode, a manufacturing method, and a light emitting device are provided. The light emitting diode includes an epitaxial structure, a first electrode, a second electrode, and an insulating layer. The epitaxial structure includes a second semiconductor layer, a light emitting layer, and a first semiconductor layer stacked in sequence from bottom to top. The first electrode is located on the first semiconductor layer and is electrically connected to the first semiconductor layer. The first electrode at least includes a first metal electrode. The first metal electrode has a strip-shaped extension portion. The insulating layer is disposed on the first semiconductor layer and the first metal electrode and has a partially thinned portion. At least part of the extension portion is located below the partially thinned portion.

### CROSS-REFERENCE TO RELATED APPLICATION

This application claims the priority benefit of China application serial no. 202211696015.7, filed on Dec. 28, 2022. The entirety of the above-mentioned patent application is hereby incorporated by reference herein and made a part of this specification.

### BACKGROUND

### Technical Field

The disclosure relates to the technical field of semiconductor manufacturing, and in particular, relates to a light emitting diode, a manufacturing method, and a light emitting device.

### Description of Related Art

Due to advantages such as low costs, high luminous efficiency, energy conservation, and environmental protection, light emitting diodes (LEDs) are widely used in lighting, visible light communications, luminous displays, and other scenarios. LED chips are categorized into three structures: the lateral structure, the flip-chip structure, and the vertical structure. Compared to the conventional lateral chips, the flip chips have the advantages of high current, reliability, and ease of use, so the flip chips have gained large-scale application at present.

The flip-chip structure of a light emitting diode means that the lateral chip is turned upside down, so that the light excited by the light emitting layer is emitted directly from the other side of the electrode. The light-emitting diodes designed based on this flip-chip structure are called the flip-chip light emitting diodes. As shown in FIG. 1, at present, the protruding structure of the extension portion of the metal electrode of the flip chip falls in the working region of the push-up pin. When the die is packaged, the push-up pin directly pushes against the front surface of the chip. But when the push-up pin pushes against the protruding structure of the extension portion of the metal electrode, the push-up pin will easily push through the metal electrode and insulating layer and may even push and crack the epitaxial structure (as shown in FIG. 2), so chip abnormalities may occur, and the risk of leakage may surface.

Currently, the working region of the push-up pin is bypassed mainly by changing the position of the extension portion of the contact electrode. However, when the structural shape or position of the contact electrode changes to a certain extent, the current inside the light emitting diode will become abnormal, so the problem of uneven light emission may occur in the light emitting diode. Therefore, how to prevent the push-up pin from pushing against the protruding structure of the extension portion of the metal electrode while ensuring uniform light emission in the light emitting diode is an urgent technical problem that needs to be solved.

### SUMMARY

The disclosure provides a light emitting diode at least including an epitaxial structure, a first electrode, a second electrode, and an insulating layer. The epitaxial structure includes a second semiconductor layer, a light emitting layer, and a first semiconductor layer stacked in sequence from bottom to top. The first electrode is located on the first semiconductor layer and is electrically connected to the first semiconductor layer. The second electrode is located on the second semiconductor layer and is electrically connected to the second semiconductor layer. The first electrode at least includes a first metal electrode, and the first metal electrode has a strip-shaped extension portion. The insulating layer is located at least on the first semiconductor layer and the first metal electrode. The insulating layer has a partially thinned portion, and at least part of the extension portion is located below the partially thinned portion of the insulating layer.

The disclosure further provides a manufacturing method of a light emitting diode, and the method includes the following steps. An epitaxial structure including a second semiconductor layer, a light emitting layer, and a first semiconductor layer stacked in sequence from bottom to top is provided. A first metal electrode is manufactured, and this step includes depositing the first metal electrode on the first semiconductor layer, wherein the first metal electrode has a strip-shaped extension portion. An insulating layer covering at least the first semiconductor layer and the first metal electrode is deposited. Part of the insulating layer above the extension portion of the first metal electrode is thinned through a removal process to form a partially thinned portion of the insulating layer.

The disclosure further provides a light emitting device using the light emitting diode according to any one of the above.

In the light emitting diode provided by the disclosure, the partially thinned portion is provided on the insulating layer, such that at least part of the extension portion is located below the partially thinned portion of the insulating layer. In this way, the push-up pin does not push through the protruding structure of the metal electrode and does not cause chip abnormality. Further, the problem of uneven light emission caused by changes in the current due to changes in the structural shape or position of the contact electrode may also be prevented.

Additional features and advantages of the disclosure will be set forth in the following specification, and in part will be apparent from the specification or can be learned by practice of the disclosure.

### BRIEF DESCRIPTION OF THE DRAWINGS

To make the technical solutions provided in the embodiments of the disclosure or the prior art more clearly illustrated, several accompanying drawings required by the embodiments or the prior art for description are briefly introduced as follows. Obviously, the drawings in the following description are some embodiments of the disclosure, and for a person having ordinary skill in the art, other drawings can be obtained based on these drawings without any inventive effort.

FIG. 1 is a schematic picture of a protruding structure of an extension portion of a metal electrode located in a working region of a push-up pin in a light emitting diode provided by the prior art.

FIG. 2 is a schematic picture of the push-up pin piercing the metal electrode and damaging the protruding structure in the light emitting diode provided by the prior art.

FIG. 3 is a schematic cross-sectional front view of a light emitting diode according to an embodiment of the disclosure.

FIG. 4 is a schematic cross-sectional top view of the light emitting diode according to an embodiment of the disclosure.

FIG. 5 is a schematic cross-sectional side view of the light emitting diode according to an embodiment of the disclosure.

FIG. 6A and FIG. 6B are schematic top views of the light emitting diode according to another embodiment of the disclosure.

FIG. 7 is a schematic cross-sectional side view of a thinned protruding structure according to an embodiment of the disclosure.

FIG. 8 is a schematic cross-sectional side view of the light emitting diode according to another embodiment of the disclosure.

FIG. 9 is a schematic cross-sectional front view of the light emitting diode according to other embodiments of the disclosure.

FIG. 10 to FIG. 12 are schematic diagrams of a process of a manufacturing method of a light emitting diode according to the disclosure.

### DESCRIPTION OF THE EMBODIMENTS

In order to make the objectives, technical solutions, and advantages of the embodiments of the disclosure more clearly, the technical solutions in the embodiments of the disclosure will be clearly and completely described in the following paragraphs together with the accompanying drawings in the embodiments of the disclosure. The technical features designed in different embodiments of the disclosure described in the following paragraphs can be combined with one another as long as they do not conflict with one another.

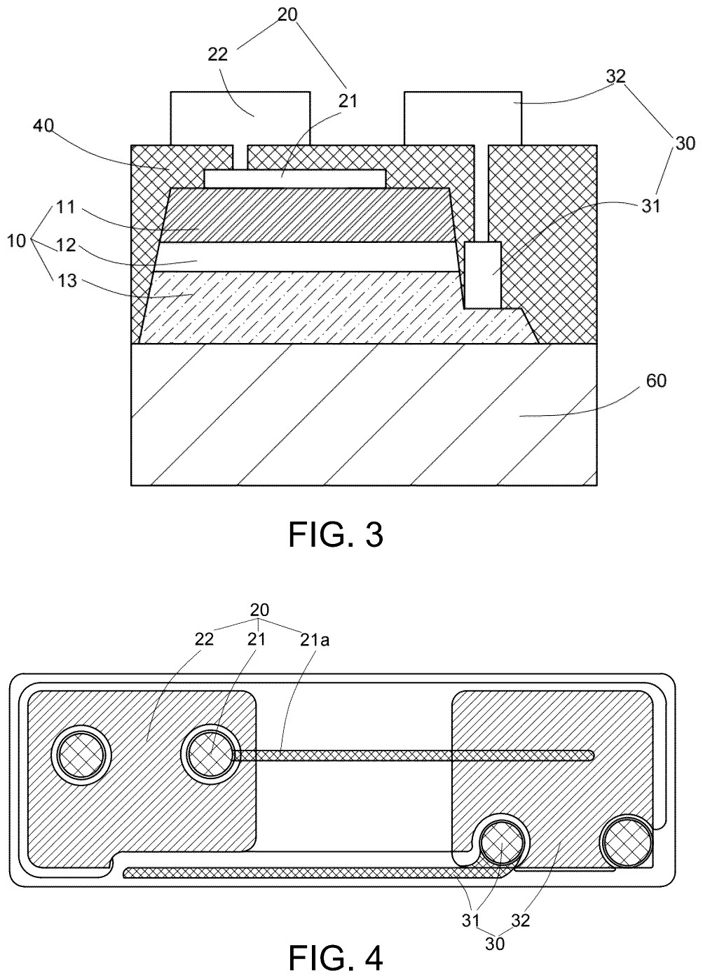

With reference to FIG. 3, FIG. 3 is a schematic cross-sectional view of a light emitting diode according to an embodiment of the disclosure. In order to achieve at least one of the advantages or other advantages, an embodiment of the disclosure provides a light emitting diode at least including an epitaxial structure 10, a first electrode 20, a second electrode 30, and an insulating layer 40.

The epitaxial structure 10 has a first surface and a second surface opposite to each other. A substrate 60 is provided on the second surface side of the epitaxial structure 10. The substrate 60 may be a transparent substrate, a non-transparent substrate, or a translucent substrate. The transparent substrate or the translucent substrate may allow the light radiated by a light emitting layer 12 to pass through the substrate 60 and reach a side of the substrate 60 away from the epitaxial structure 10. For instance, the substrate 60 may be any one of a sapphire flat substrate, a sapphire patterned substrate, a silicon substrate, a silicon carbide substrate, a gallium nitride substrate, and a glass substrate. In some embodiments, thinning or removal may also be performed to form a thin-film light emitting diode chip. In this embodiment, the light emitting diode is preferably a sapphire substrate. In other embodiments, the epitaxial structure 10 may be connected to the substrate 60 through an adhesive layer (not shown).

The epitaxial structure 10 includes a second semiconductor layer 13, the light emitting layer 12, and a first semiconductor layer 11 stacked in sequence from bottom to top on the substrate 60. As an example, the first semiconductor layer 11 and the second semiconductor layer 13 have different conductivity types, which may be N-type or P-type. Radiative recombination may occur on the light emitting layer 12. To be specific, the light emitting layer 12 may be a single quantum well layer or a multiple quantum well layer. For instance, the first semiconductor layer 11 may be an N-type GaN layer, or the second semiconductor layer 13 may be an N-type GaN layer. Herein, the N-type is a silicon-based doping type, and the P-type is a magnesium-based doping type. Certainly, the epitaxial structure 10 may also include other layer materials, such as window layers or ohmic contact layers, which are arranged into different multi-layers according to different doping concentrations or component contents.

The first electrode 20 is located on the first semiconductor layer 11 on one side of the first surface and is electrically connected to the first semiconductor layer 11. The second electrode 30 is located on the second semiconductor layer 13 on one side of the first surface and is electrically connected to the second semiconductor layer 13. The first electrode 20 at least includes a first metal electrode 21 and a first pad electrode 22, and the second electrode 30 at least includes a second metal electrode 31 and a second pad electrode 32. As an example, with reference to FIG. 4, the first metal electrode 21 may include two portions: a dot-shaped portion (not labeled) and an extension portion 21a. Herein, the dot-shaped portion is used to achieve the longitudinal transmission of current between the first metal electrode 21 and the first pad electrode 22 and may be in the shape of a circular dot or an elliptical dot. The extension portion 21a extends a specific length from the dot-shaped portion along a horizontal direction, is in a strip shape, and is used to achieve lateral transmission of current. Exemplarily, as shown in FIG. 4, in order to improve the uniform spread of current in the light emitting diode, the extension portion 21a of the first metal electrode 21 extends from below the first pad electrode 22 through or around a center of the epitaxial structure 10 toward the second pad electrode 32. A thickness of the first metal electrode 21 ranges from 0.3 microns to 3 microns. A width of the extension portion 21a is 2 microns to 10 microns. Preferably, the first electrode 20 and the second electrode 30 may be metal electrodes. That is, a material of the first electrode 20 and the second electrode 30 may be metal, such as one or a combination of nickel, gold, chromium, titanium, platinum, palladium, rhodium, iridium, aluminum, tin, indium, tantalum, copper, cobalt, iron, ruthenium, zirconium, tungsten, and molybdenum.

With reference to FIG. 3 again, the insulating layer 40 at least covers the epitaxial structure 10 and the first metal electrode 21. To be specific, the insulating layer 40 at least includes one or a combination of a SiO₂ layer, a Si₃N₄ layer, an Al₂O₃ layer, an AlN layer, and a DBR layer and is not limited to the examples listed herein. As an example, a distributed Bragg reflector layer (DBR layer) may be preferred.

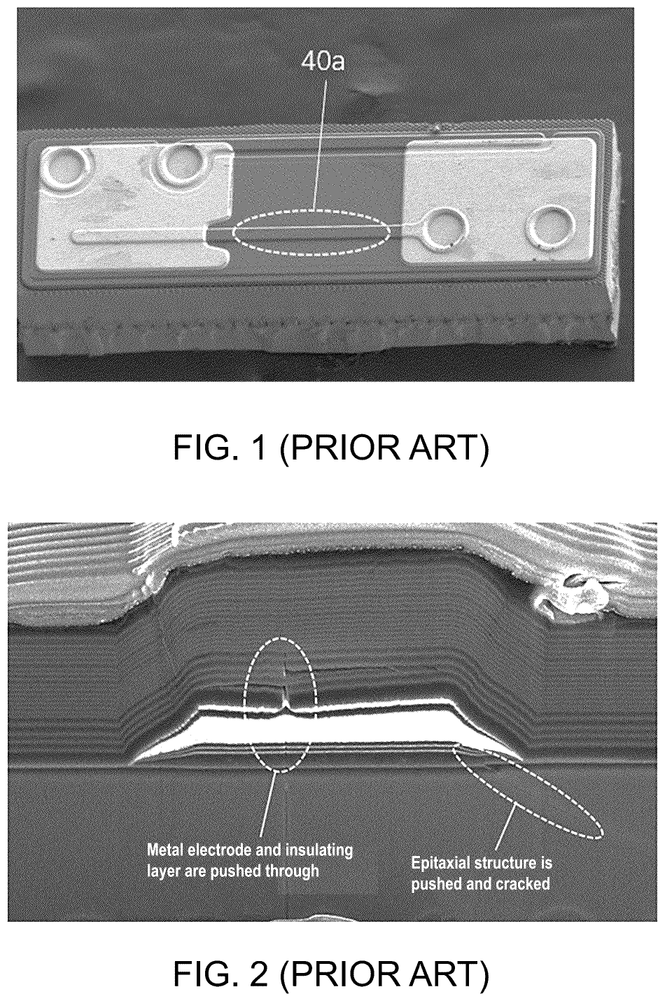

With reference to FIG. 1, when the insulating layer 40 covers the first surface of the epitaxial structure 10 and the first metal electrode 21, a protruding structure 40a is formed above the extension portion 21a of the first metal electrode 21. During the subsequent packaging and die bonding process, when a push-up pin pushes against a front surface of a chip, the protruding structure 40a may be pushed easily. This makes a chip region where the push-up pin contacts uneven, and electrode deformation is thus generated, the insulating layer is pushed through, and the epitaxial structure is pushed and cracked. Therefore, in this embodiment, the insulating layer 40 is improved to avoid the above situation. To be specific, the insulating layer 40 has a partially thinned portion 41, and at least part of the extension portion 21a is located below the partially thinned portion 41 of the insulating layer 40. Exemplarily, part of a structure of the extension portion 21a is located below the partially thinned portion 41 of the insulating layer 40. The protruding structure 40a is thinned by arranging the partially thinned portion 41 on the insulating layer 40 located above the extension 21a, so that electrode deformation, pushing through of the insulating layer, and pushing and cracking of the epitaxial structure caused by uneven contact caused by the push-up pin pushing against the protruding structure 40a may become less likely to occur.

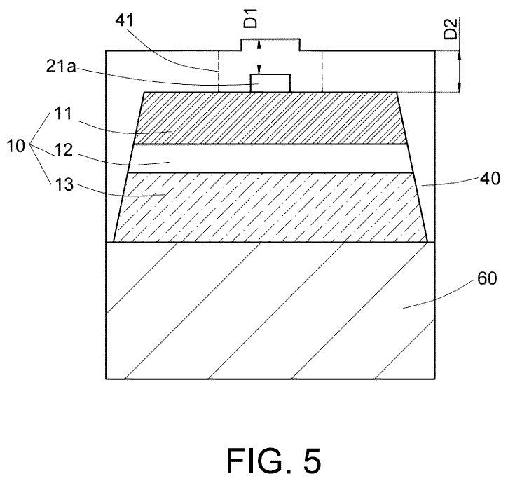

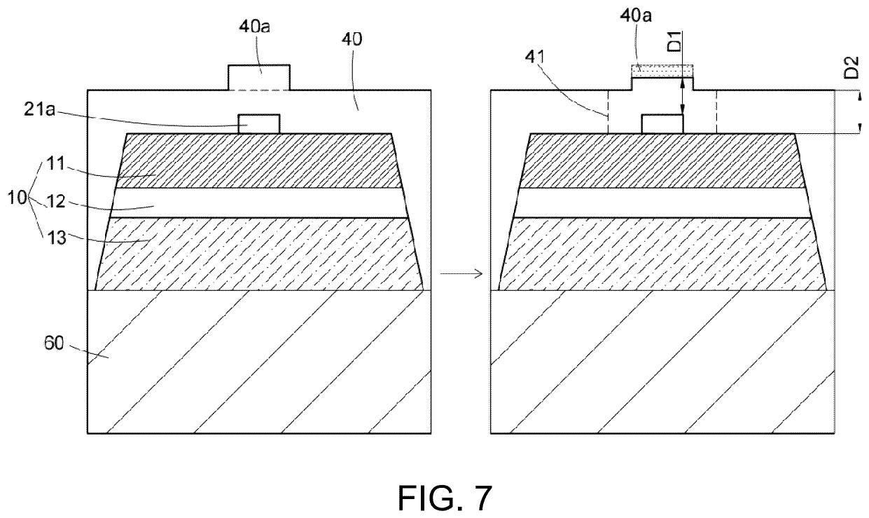

Preferably, the partially thinned portion 41 of the insulating layer 40 has a thinner thickness relative to the remaining portions of the insulating layer 40. With reference to FIG. 5, the partially thinned portion 41 of the insulating layer 40 has a first thickness D1, and the first thickness D1 is a minimum thickness of the insulating layer 40. The first thickness D1 may be measured from an upper surface of the extension portion 21a of the first metal electrode 21 located below the partially thinned portion 41 of the insulating layer 40 to an upper surface of the insulating layer 40. The insulating layer 40 has a second thickness D2, and the second thickness D2 is a maximum thickness of other portions of the insulating layer 40 located around the partially thinned portion 41. A thickness from a lower surface to the upper surface of the insulating layer 40 may be measured by selecting one position from a region away from the partially thinned portion 41 or from above the first semiconductor layer 11 around the extension portion 21a of the first metal electrode 21. The first thickness D1 is less than the second thickness D2. As an example, with reference to FIG. 7, the partially thinned portion 41 is located above at least part of the extension portion 21a. The protruding structure 40a is formed because the insulating layer 40 covers the extension portion 21a, so that the location of the partially thinned portion 41 includes the protruding structure 40a. The partially thinned portion 41 may be reduced to the first thickness D1 by thinning the protruding structure 40a as shown in FIG. 7, so that the first thickness D1 is lower than the second thickness D2.

Through the abovementioned definition of the first thickness D1 and the second thickness D2, a height difference between an upper surface of the partially thinned portion 41 of the insulating layer 40 and the upper surface of the insulating layer 40 around the partially thinned portion 41 is reduced. Therefore, the push-up pin may not push through the protruding structure 40a of the metal electrode, so chip abnormality thus may not occur. In addition, the problem of uneven light emission caused by changes in current caused by changing the structural shape or position of the metal electrode in the prior art may also be avoided. Therefore, in LED production and application, the yield rate of the products is greatly improved, and important practical application values are thus provided.

In a preferred embodiment, a thickness difference between the second thickness D2 and the first thickness D1 is less than or equal to a thickness of the extension portion 21a. To be specific, the upper surface of the partially thinned portion 41 may be thinned so that the thickness difference between the second thickness D2 and the first thickness D1 is less than or equal to the thickness of the extension portion 21a. That is, by reducing the height difference between the upper surface of the partially thinned portion 41 and the upper surface of the insulating layer 40 around the partially thinned portion 41, damage to the extension portion 21a located below the partially thinned portion 41 due to uneven contact may be effectively reduced when the push-up pin contacts the partially thinned portion 41.

As an example, the second thickness D2 ranges from 1 micron to 6 microns. Through the setting of this range, the protective and insulating effect of the insulating layer 40 on the metal electrode is ensured. Further, when the insulating layer 40 is a reflective layer, in order to ensure the reflection effect of the insulating layer 40, the second thickness D2 of the insulating layer 40 may range from 2 microns to 5 microns.

Preferably, with reference to FIG. 4 again, in order to optimize the spread of current, when viewed from above the light emitting diode toward the epitaxial structure 10, the extension portion 21a is linear and extends from the first pad electrode 22 through the center of the epitaxial structure 10 and parallel to an extension portion of the second metal electrode 31. Further, the extension portion 21a may extend below the second pad electrode 32, so that the injected current may spread laterally in the light emitting diode evenly.

Optionally, the extension portion 21a is linear, extends from below the first pad electrode 22 and parallel to the extension portion of the second metal electrode 31 toward the second pad electrode 32, and extends without passing through the center of the epitaxial structure 10.

Optionally, the extension portion 21a is in a non-linear shape (e.g., an arc shape), extends from below the first pad electrode 22 and without being parallel to the extension portion of the second metal electrode 31 toward the second pad electrode 32, and extends without passing through the center of the epitaxial structure 10.

In an embodiment, when viewed from above the light emitting diode toward the epitaxial structure 10, the partially thinned portion 41 of the insulating layer 40 is located between the first pad electrode 22 and the second pad electrode 32. During the packaging process of the light emitting diode, a region between the first pad electrode 22 and the second pad electrode 32 is a region where the push-up pin works. Therefore, the partially thinned portion 41 of the insulating layer 40 is arranged in this region, and the partially thinned portion 41 may be thinned through a removal process, so that the first thickness D1 is lower than the second thickness D2, and that the push-up pin is effectively prevented from pushing through the metal electrode. In the general packaging process, it is necessary to use a circular push-up pin to act on a center of a light emitting diode to lift up the light emitting diode for die bonding. Therefore, the partially thinned portion 41 of the insulating layer 40 may be located in the center of the light emitting diode.

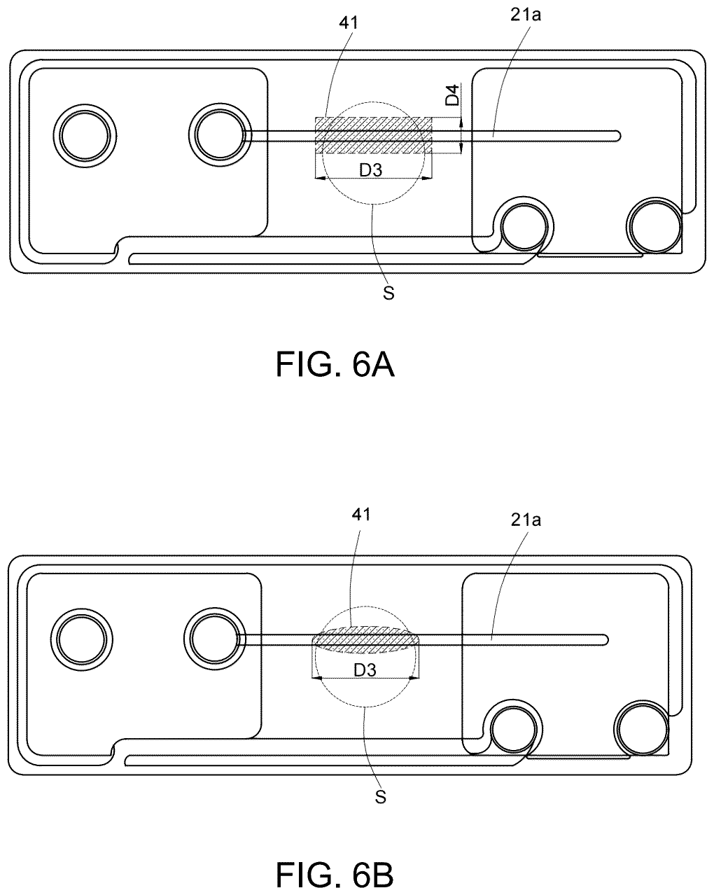

In some embodiments, when viewed from above the light emitting diode toward the epitaxial structure 10, a size range of a push-up pin working region S in a length direction of the extension portion 21a falls within a size range of the partially thinned portion 41 of the insulating layer 40 in the length direction of the extension portion 21a. As shown in FIG. 6A, the partially thinned portion 41 of the insulating layer 40 includes the push-up pin working region S in the length direction of the extension portion 21a. Further, the partially thinned portion 41 may be a strip-shaped region located above the extension portion 21a. That is, a strip length (i.e., a maximum width D3) of the partially thinned portion 41 is greater than or equal to a size of the push-up pin working region S in the length direction of the extension portion 21a. As an example, the maximum width D3 is between 5 microns and 100 microns, and a minimum width D4 is between 3 microns and 10 microns. Preferably, for instance, as shown in FIG. 6A, the minimum width D4 of the partially thinned portion 41 of the insulating layer 40 in a width direction of the light emitting diode shall be greater than the width of the extension portion 21a. For instance, the minimum width D4 is 1 micron to 4 microns larger than the width of the extension portion.

In other embodiments, for instance, as shown in FIG. 6B, optionally, the partially thinned portion 41 may also be an elliptical region located above the extension portion 21a. However, the elliptical region may cause excessive portions of the insulating layer region to be thinned, resulting in reduced protection or reduced reflectivity and reduced photoelectric energy absorption. The elliptical region has the maximum width D3. The partially thinned portion 41 of the insulating layer 40 has the maximum width D3 in the length direction of the extension portion 21a. The maximum width D3 is greater than the size of the push-up pin working region S in the length direction of the extension portion 21a and may be adjusted specifically according to the actual different specifications of the push-up pin and the different sizes of the extension portion 21a.

It should be noted that the maximum width D3 refers to the longest dimension formed by the partially thinned portion 41 of the insulating layer 40 in the length direction of the extension portion 21a. In FIG. 6A, the maximum width D3 is represented by the long side of the strip region, and in FIG. 6B, the maximum width D3 is represented by the long axis of the elliptical region.

It should also be noted that, according to the inventive concept, the partially thinned portion 41 may also be a region of any shape (e.g., a diamond-shaped region or a crescent-shaped region) located above part of the structure of the extension portion 21a. The specific position may be set according to the size and position of the push-up pin working region S.

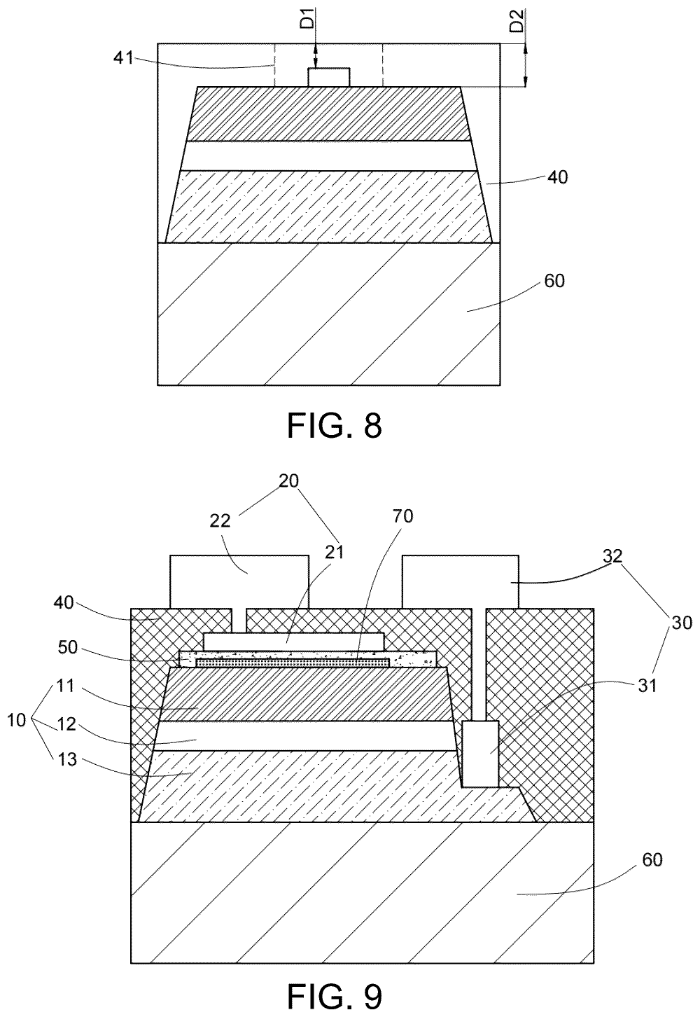

Further, in order to more effectively prevent the protruding structure 40a from affecting the operation of the push-up pin, in this embodiment, the upper surface of the partially thinned portion 41 of the insulating layer 40 is at a same level as the upper surface of the insulating layer 40 located around the extension portion 21a. To be specific, with reference to FIG. 8, the protruding structure 40a located in the partially thinned portion 41 is removed through a removal process, so that the upper surface of the partially thinned portion 41 is at the same level as the upper surface of the insulating layer 40 located around the extension portion 21a. This ensures that there is no height difference between the two, and when the push-up pin acts on the partially thinned portion 41, the surface is flat. Further, the problem of the push-up pin pushing and cracking the epitaxial structure 10 or damaging the metal electrode due to uneven contact is also prevented from occurring. Further, a working window of the push-up pin is effectively expanded, and the reliability of the process of the light emitting diode is further improved.

In an embodiment, as shown in FIG. 9, the light emitting diode further includes a current spreading layer 50 and a current blocking layer 70. The current spreading layer 50 is located between the first semiconductor layer 11 and the first metal electrode 21 and is in contact with the first semiconductor layer 11 and the first metal electrode 21. Herein, the current spreading layer 50 forms an ohmic contact with the first semiconductor layer 11 to enhance the lateral transmission of current in the horizontal direction and guide the current to be injected into the first semiconductor layer 11 more uniformly. The current spreading layer 50 covers the first semiconductor layer 11 almost frontally.

As an example, a material of the current spreading layer 50 may be a metal oxide. Further, the current spreading layer 50 may be a relatively transparent material that allows at least part of the radiation from the light emitting layer 12 to pass through, such as one or a combination of ITO, IZO, InO, SnO, GTO, GZO, and ZnO. The disclosure is not limited to the examples listed here. A thickness of the current spreading layer 50 is preferably 30 nm to 200 nm, such as 30 nm, 50 nm, 70 nm, 100 nm, 150 nm, or 200 nm.

The current blocking layer 70 is located above the first semiconductor layer 11 and below the current spreading layer 50 and is configured to block vertical and longitudinal current transmission between the first metal electrode 21 and the first semiconductor layer 11, thereby facilitating lateral current spreading through the current spreading layer 50. Preferably, when viewed from above the light emitting diode toward the epitaxial structure 10, the width of the current blocking layer 70 is greater than the width of the extension portion 21a of the first metal electrode 21. Exemplarily, shapes of the current blocking layer 70 and the first metal electrode 21 are the same. Further, the current blocking layer 70 is located below the first metal electrode 21, and further, is located at least below the extension portion 21a. The current blocking layer 70 is also in a strip shape, and its width is greater than the width of the extension portion 21a of the first metal electrode 21, for example, 3 microns to 8 microns wide.

As an example, a material of the current blocking layer 70 is an insulating material, which may be an oxide. Further, the current blocking layer 70 may be a relatively transparent material that allows at least part of the radiation from the light emitting layer 12 to pass through, such as one or a combination of silicon oxide, silicon nitride, and other materials. The disclosure is not limited to the examples listed here. A thickness of the current blocking layer 70 is 200 nm to 500 nm.

Further, if the current blocking layer 70 is provided between the first semiconductor layer 11 and the first metal electrode 21, the thickness difference between the second thickness D2 and the first thickness D1 is less than or equal to a sum of the thicknesses of the extension portion 21a and the current blocking layer 70. Through the above arrangement, it is defined that the upper surface of the partially thinned portion 41 of the insulating layer 40 is lower than or flush with the upper surface of the insulating layer 40 around the partially thinned portion 41 when the current blocking layer 70 is provided. In this way, the possibility of deformation of the metal electrode or pushing and cracking of the epitaxial structure 10 caused by contact of the push-up pin is effectively prevented.

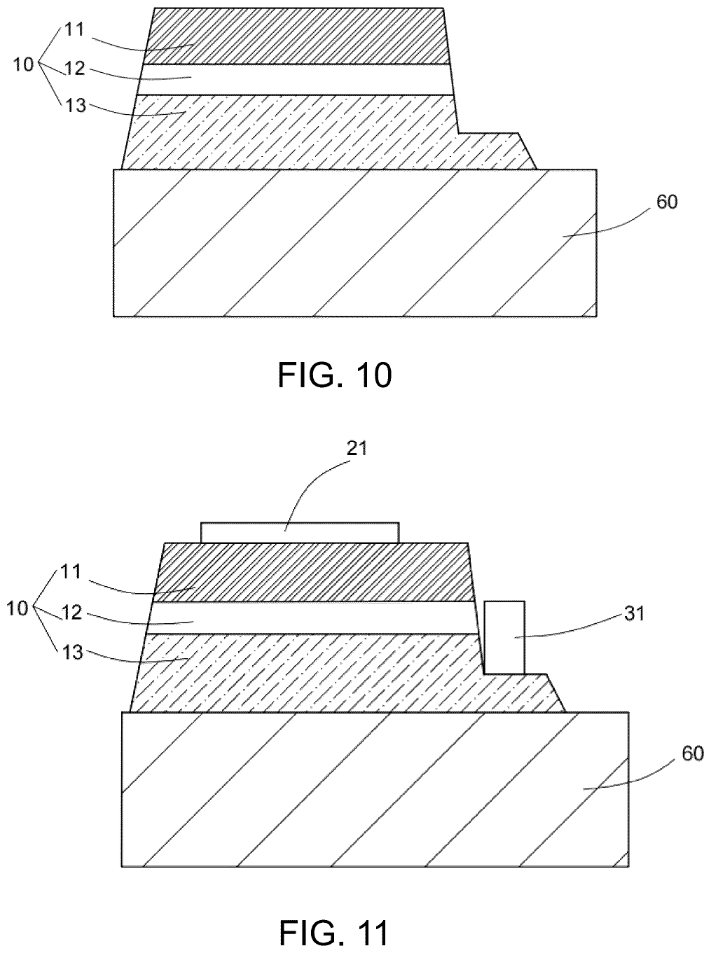

FIG. 10 to FIG. 12 are schematic diagrams of a process of a manufacturing method of a light emitting diode. The manufacturing method of the light emitting diode provided by the disclosure is described in detail in the following paragraphs with reference to the schematic diagrams.

With reference to FIG. 10, an epitaxial structure 10 having a first surface and a second surface opposite to each other is provided. The epitaxial structure 10 includes a second semiconductor layer 13, a light emitting layer 12, and a first semiconductor layer 11 stacked in sequence. The epitaxial structure 10 is bonded onto a substrate 60. To be specific, the epitaxial structure 10 may be formed by techniques such as metal-organic chemical vapor deposition (MOCVD), molecular beam deposition (MBE), or hydride vapor deposition (HVPE). Further, a current blocking layer 70 and a current spreading layer 50 may also be deposited on the first surface of the epitaxial structure 10. Moreover, the epitaxial structure 10 is etched from the first surface to the second surface, and a portion of the second semiconductor layer 13 is exposed to form a mesa. Optionally, according to actual needs, the current spreading layer 50 and/or the current blocking layer 70 may be formed on the first semiconductor layer to optimize the uniformity of lateral current spreading.

With reference to FIG. 11, a first metal electrode 21 is manufactured, and this step includes depositing the first metal electrode 21 on the first surface of the epitaxial structure 10. Herein, the first metal electrode 21 has an extension portion 21a. A second metal electrode 31 is manufactured, and this step includes depositing the second metal electrode 31 on the mesa of the epitaxial structure 10.

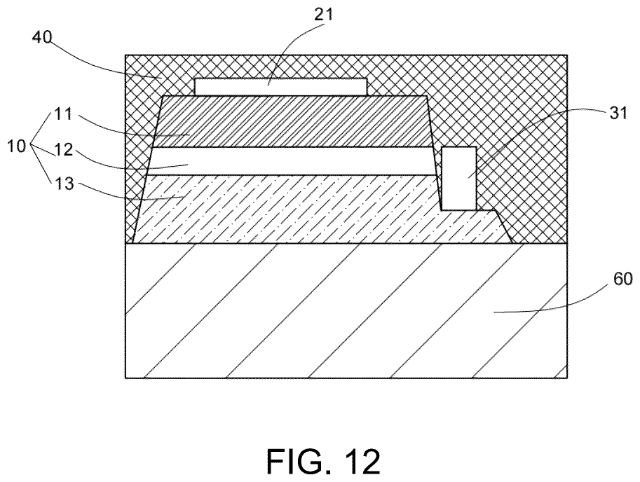

With reference to FIG. 12, an insulating layer 40 is deposited, and the insulating layer 40 at least covers the first surface of the epitaxial structure 10 and the first metal electrode 21. In this embodiment, the insulating layer 40 may completely cover the epitaxial structure 10, the first metal electrode 21, and the second metal electrode 31. Next, with reference to FIG. 7, part of the insulating layer 40 above the extension portion 21a of the first metal electrode 21 is thinned through a removal process to form a partially thinned portion 41 of the insulating layer 40. The specific thickness thinning may be performed with reference to the aforementioned relationship between the first thickness D1 and the second thickness D2, so description thereof is not repeated herein.

In a preferred embodiment, the removal process is at least one of laser, dry etching, and wet etching. The specific selection may be made according to actual needs and is not limited herein. In this embodiment, the ISO dry etching process is preferred.

Further, with reference to FIG. 3, a first pad electrode 22 and a second pad electrode 32 are manufactured on the basis of the above. Through holes are provided on the insulating layer. The first pad electrode 22 and the second pad electrode 32 are deposited on the insulating layer 40 and are electrically connected to the first metal electrode 21 and the second metal electrode 31 respectively through the through holes on the insulating layer 40.

The disclosure further provides a light emitting device using the light emitting diode as described in any of the above embodiments, so that the performance of the light emitting device may be effectively improved.

In view of the foregoing, in the light emitting diode provided by the disclosure, by changing the thickness of the insulating layer, the chip abnormality caused by the deformation of the metal electrode or pushing and cracking of the epitaxial structure caused by the action of the push-up pin may be effectively avoided. Further the problem of uneven light emission caused by changes in the current due to changes in the structural shape or position of the contact electrode may also be prevented. The overall performance and reliability of the light emitting diode is thereby improved.

Finally, it is worth noting that the foregoing embodiments are merely described to illustrate the technical means of the disclosure and should not be construed as limitations of the disclosure. Even though the foregoing embodiments are referenced to provide detailed description of the disclosure, people having ordinary skill in the art should understand that various modifications and variations can be made to the technical means in the disclosed embodiments, or equivalent replacements may be made for part or all of the technical features; nevertheless, it is intended that the modifications, variations, and replacements shall not make the nature of the technical means to depart from the scope of the technical means of the embodiments of the disclosure.

What is claimed is:

1. A light emitting diode, comprising:
an epitaxial structure comprising a second semiconductor layer, a light emitting layer, and a first semiconductor layer stacked in sequence from bottom to top;
a first electrode located on the first semiconductor layer and electrically connected to the first semiconductor layer;
a second electrode located on the second semiconductor layer and electrically connected to the second semiconductor layer,
wherein the first electrode at least comprises a first metal electrode, and the first metal electrode has a strip-shaped extension portion; and
an insulating layer located at least on the first semiconductor layer and the first metal electrode, wherein the insulating layer has a partially thinned portion, and at least part of the extension portion is located below the partially thinned portion of the insulating layer.

2. The light emitting diode according to claim 1, wherein the partially thinned portion of the insulating layer has a first thickness, the insulating layer around the partially thinned portion has a second thickness, the second thickness is a maximum thickness of the insulating layer, and the first thickness is less than the second thickness.

3. The light emitting diode according to claim 2, wherein the second thickness ranges from 1 micron to 6 microns.

4. The light emitting diode according to claim 2, wherein a thickness difference between the second thickness and the first thickness is less than or equal to a thickness of the extension portion.

5. The light emitting diode according to claim 2, further comprising:
a current blocking layer located between the first semiconductor layer and the extension portion of the first metal electrode, wherein when viewed from above the light emitting diode toward the epitaxial structure, the current blocking layer is in a strip shape, and a width of the current blocking layer is greater than a width of the extension portion of the first metal electrode.

6. The light emitting diode according to claim 5, wherein a thickness difference between the first thickness and the second thickness is less than or equal to a sum of thicknesses of the extension portion and the current blocking layer.

7. The light emitting diode according to claim 1, wherein a thickness of the first metal electrode ranges from 0.3 microns to 3 microns.

8. The light emitting diode according to claim 1, wherein part of a structure of the extension portion is located below the partially thinned portion of the insulating layer.

9. The light emitting diode according to claim 1, wherein when viewed from above the light emitting diode toward the epitaxial structure, the partially thinned portion of the insulating layer is located at or away from a center of the light emitting diode.

10. The light emitting diode according to claim 1, wherein an upper surface of the partially thinned portion of the insulating layer is at a same level as an upper surface of the insulating layer located around the extension portion.

11. The light emitting diode according to claim 1, wherein the first electrode further comprises a first pad electrode, and the first pad electrode is located on the insulating layer and is electrically connected to the first semiconductor layer through the first metal electrode,
the second electrode comprises a second pad electrode and a second metal electrode, and the second pad electrode is located on the insulating layer and is electrically connected to the second semiconductor layer through the second metal electrode.

12. The light emitting diode according to claim 11, wherein when viewed from above the light emitting diode toward the epitaxial structure, the extension portion extends from below the first pad electrode through or around a center of the epitaxial structure toward the second pad electrode.

13. The light emitting diode according to claim 11, wherein when viewed from above the light emitting diode toward the epitaxial structure, the partially thinned portion of the insulating layer is located between the first pad electrode and the second pad electrode.

14. The light emitting diode according to claim 1, wherein the partially thinned portion of the insulating layer is in a strip shape.

15. The light emitting diode according to claim 1, wherein the partially thinned portion of the insulating layer has a maximum width, and the maximum width is between 5 microns and 100 microns.

16. The light emitting diode according to claim 1, further comprising:
a substrate disposed on a side of the second semiconductor layer away from the first semiconductor layer.

17. A manufacturing method of a light emitting diode, comprising:
providing an epitaxial structure comprising a second semiconductor layer, a light emitting layer, and a first semiconductor layer stacked in sequence from bottom to top;
manufacturing a first metal electrode comprising depositing the first metal electrode on the first semiconductor layer, wherein the first metal electrode has a strip-shaped extension portion;
depositing an insulating layer covering at least the first semiconductor layer and the first metal electrode; and
thinning part of the insulating layer above the extension portion of the first metal electrode through a removal process to form a partially thinned portion of the insulating layer.

18. The manufacturing method of the light emitting diode according to claim 17, wherein the removal process comprises at least one of laser, dry etching, and wet etching.

19. A light emitting device using the light emitting diode according to claim 1.
